(19) United States
(12) Patent Application Publication
(10) Pub. No.: US 2016/0032452 A1
(43) Pub. Date: Feb. 4, 2016

(54) Atomic Layer Deposition Method Using Source Precursor Transformed by Hydrogen Radical Exposure

(71) Applicant: Veeco ALD Inc., Fremont, CA (US)

(72) Inventors: Sang In Lee, Los Altos Hills, CA (US); Chang Wan Hwang, Hwaseong-si (KR)

(21) Appl. No.: 14/808,152

(22) Filed: Jul. 24, 2015

Related U.S. Application Data
(60) Provisional application No. 62/032,688, filed on Aug. 4, 2014.

(51) Int. Cl. C23C 16/455; C23C 16/18; C23C 16/50

(52) U.S. Cl. CPC C23C 16/45525; C23C 16/50; C23C 16/18

(57) ABSTRACT

A film of source precursor molecules injected onto a substrate are reacted with hydrogen radicals, such as those produced in a hydrogen plasma, prior to reaction with a reactant precursor. This replaces the functional groups of the reactant precursor (e.g., methyl groups in alkyl groups) with hydrogen, thus reducing the overall size of the source precursor molecule. An additional cycle of source precursor molecules are injected onto the substrate, some of which occupy portions of the substrate surface left unoccupied by the now absent methyl functional groups. This increases the density of source precursor molecules (i.e., reaction sites) on the substrate. The reactivity of the source precursor molecules exposed to hydrogen radicals (or an H₂ plasma) is also increased.

### CROSS-REFERENCE TO RELATED APPLICATIONS

This application claims the benefit under 35 U.S.C. §119(e) of U.S. Provisional Application No. 62/032,688, filed Aug. 4, 2014, which is incorporated by reference in its entirety.

### BACKGROUND

1. Field of Art

The present invention relates to depositing one or more layers of materials on a substrate using atomic layer deposition (ALD).

2. Description of Related Art

Atomic layer deposition (ALD) is a thin film deposition technique for depositing one or more layers of material on a substrate. ALD uses two types of species to deposit a layer of material: a source precursor and a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor. ALD can be a slow process that can take an extended amount of time or many repetitions before a layer of desired thickness can be obtained. Hence, to expedite the process, a vapor deposition reactor with a unit module (a “linear injector”), such as that described in U.S. Pat. No. 8,333,839 (or other similar devices), may be used to expedite the ALD process. The unit module includes an injection unit and an exhaust unit for a source precursor (a source module), and an injection unit and an exhaust unit for a reactant precursor (a reactant module).

A conventional ALD vapor deposition chamber has one or more sets of reactors for depositing ALD layers on substrates. As the substrate passes below the reactors, the substrate is exposed to the source precursor, a purge gas and the reactant precursor. The source precursor deposited on the substrate reacts with reactive species, including reactant precursor (or ligands thereof). The ligands of source precursor are replaced with the reactive species of reactant precursor. Other reactions include those between the source precursor and the substrate. Regardless of the reactants, example types of reactions include ligand exchange and ligand redox. This then results in deposition of a layer of material on the substrate. After exposing the substrate to the source precursor or the reactant precursor, the substrate may be exposed to purge gas to remove excess source precursor molecules or reactant precursor molecules from the substrate.

To reduce the number of iterations needed to deposit a material of a desired thickness, it is advantageous to increase the deposition rate per each ALD cycle.

### SUMMARY

Methods and systems are described for increasing the density (and improving associated physical, chemical, electrical, and optical properties) of films (also referred to interchangeably as “layers” herein) deposited using atomic layer deposition (“ALD”). Source precursor molecules, (e.g., alkyl-functionalized or other organically functionalized) metal ions injected onto a substrate are reacted with hydrogen radicals, such as those produced in a hydrogen plasma, prior to reaction with a reactant precursor. This has the effect of replacing the functional groups of the reactant precursor with hydrogen, thus reducing the overall size of the source precursor molecule. An additional cycle of source precursor molecules are then injected onto the substrate. Some of the additionally injected source precursor molecules occupy portions of the substrate surface left unoccupied by the now absent methyl functional groups. This has the effect of increasing the density of source precursor molecules (i.e., reaction sites for reactant precursor) on the substrate.

In one embodiment, a method of atomic layer deposition of the present disclosure includes injecting a metal organic source precursor onto a substrate, adsorbing the metal organic precursor on a surface of the substrate, generating hydrogen radicals, exposing the metal organic source precursor on the surface of the substrate to the hydrogen radicals, in which the hydrogen radicals react with the metal organic source precursor on the surface of the substrate, and injecting a reactant precursor onto the substrate, the reactant precursor reacting with the metal organic source precursor exposed to the hydrogen radicals.

In an embodiment of the present disclosure, an atomic layer deposition film includes a substrate having a surface, a plurality of metal organic source precursor molecules that include a first plurality of multi-valent metal ions, at least some of the multi-valent metal ions bonded to the surface of the substrate and at least one organic ligand, and a plurality of converted source precursor molecules that include a second plurality of multi-valent metal ions, at least some of the converted source precursor molecules of the second plurality bonded to the surface of the substrate and at least one hydrogen atom. Either at an intermediate state of reaction of the film or at a state in which the reaction has ceased, both the plurality of metal organic source precursor molecules and the plurality of converted source precursor molecules are disposed on the surface of the substrate.

### BRIEF DESCRIPTION OF THE DRAWINGS

FIG. 1A are schematic representations (in plan and side views) of relative molecular sizes of variously valenced metal ions functionalized with methyl groups, in an embodiment.

FIG. 1B are schematic representations (in plan and side views) of relative molecular sizes of a tetramethyl-metal organic compound and a metal tetrahydride compound, in an embodiment.

FIG. 1C is a schematic representation of the relative size reduction in a trimethyl-metal organic compound reacted to a metal trihydride compound using hydrogen plasma, in an embodiment.

FIG. 1D is a schematic representation showing increased density of metal organic molecules on a substrate after reaction with hydrogen plasma, in an embodiment.

FIG. 1E is a schematic representation showing a substrate on which are disposed source precursor molecules having both organic ligands and hydrogen ligands, in an embodiment.

FIG. 2 is a method flow diagram showing an ALD method using source precursors transformed by hydrogen radical exposure for increasing the molecular density and layer deposition rate on a substrate, in an embodiment.

FIG. 3A is a cross sectional diagram of a linear deposition device, in an embodiment.

FIG. 3B is a perspective view of a linear deposition device, in an embodiment.

FIG. 4 is a perspective view of reactors in a deposition device in an embodiment.

FIG. 5 is a cross sectional diagram illustrating the reactors taken along line A-B of FIG. 4, in an embodiment.

The figures depict various embodiments of the present disclosure for purposes of illustration only. One skilled in the art will readily recognize from the following discussion that alternative embodiments of the structures and methods illustrated herein may be employed without departing from the principles described herein.

### DETAILED DESCRIPTION OF EMBODIMENTS

### Overview

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments of the present disclosure describe methods and system for increasing the density (and improving associated physical, chemical, electrical, and optical properties) of films deposited using atomic layer deposition (“ALD”). In conventional ALD processes, molecules are injected onto a substrate as the source precursor. These source precursor molecules are adsorbed onto a surface of the substrate and, ultimately, are reacted with injected reactant precursor molecules, forming a layer of the reaction product in situ.

However, in many cases, source precursor molecules with organic ligands have large molecular radii thus lowering the areal density of molecules on the substrate surface due to steric hindrance. For example, metal ions functionalized with various organic functional groups are often used as precursors for metallic, metal oxide, metal nitride, or intermetallic compound thin films. The smallest carbon-containing organic ligand used to functionalize a metal ion is methyl (—CH₃) which is significantly larger than a metal ion itself Larger molecular size reduces the number of source precursor molecules that fit into a unit area of substrate surface (referred to herein as “areal density”) due to steric hindrance. Lower areal densities of source precursor molecules impact the deposition rate of the film deposited by ALD and the properties of the film.

To overcome this, source precursor molecules, (e.g., alkyl-functionalized metal ions) injected onto a substrate are reacted with hydrogen radicals, such as those produced in a hydrogen plasma, prior to reaction with a reactant precursor. This has the effect of replacing the functional groups of the reactant precursor (e.g., alkyl groups) with hydrogen, thus reducing the overall size of the source precursor molecule. An additional cycle of source precursor molecules are then injected onto the substrate. Some of the additionally injected source precursor molecules occupy portions of the substrate surface left unoccupied by the now absent methyl functional groups. This has the effect of increasing the areal density of source precursor molecules (i.e., reaction sites for reactant precursor) on the substrate. The reactivity of the source precursor molecules exposed to hydrogen radicals (or H₂ plasma) is also increased. Regardless, exposing source precursor molecules to hydrogen radicals prior to reaction with reactant precursor molecules increases the ALD deposition rate of material on a substrate and can improve various properties of the film.

### Schematic Illustrations

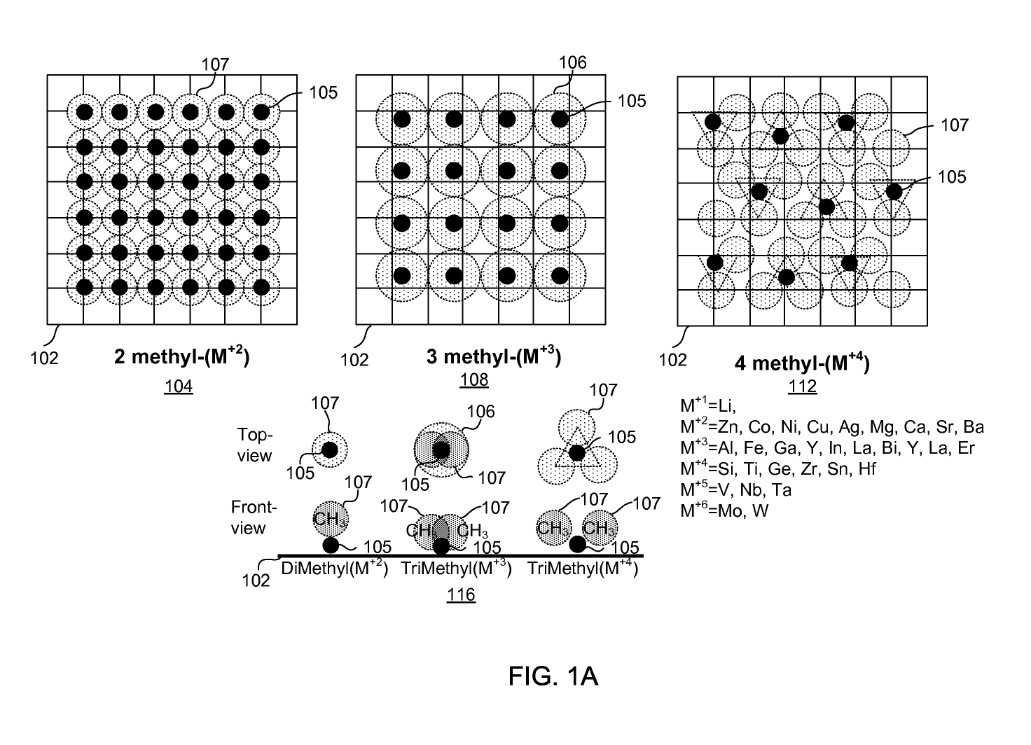

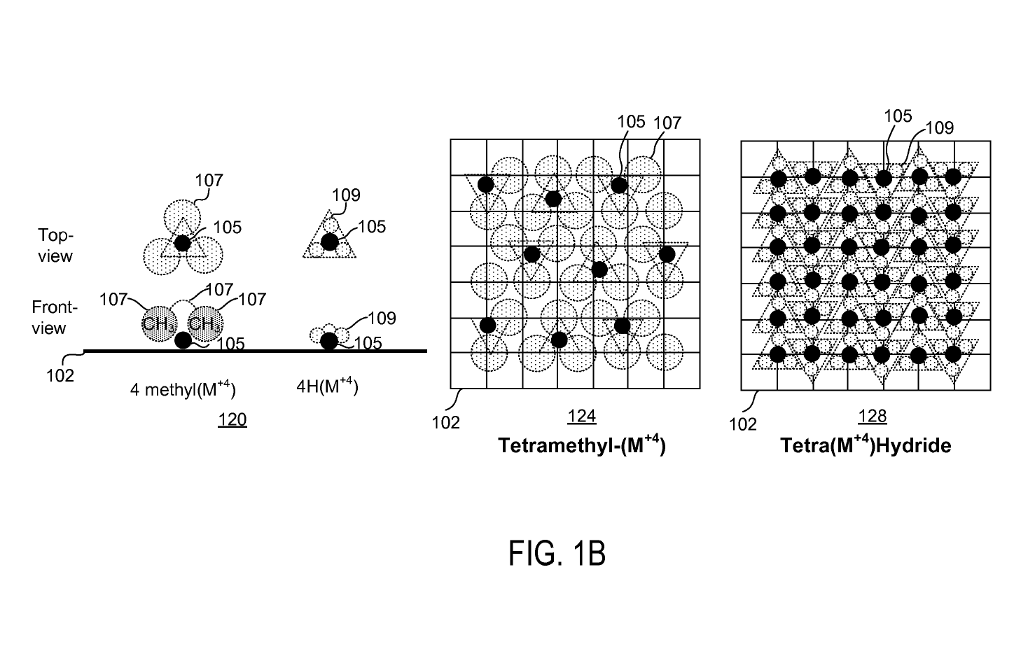

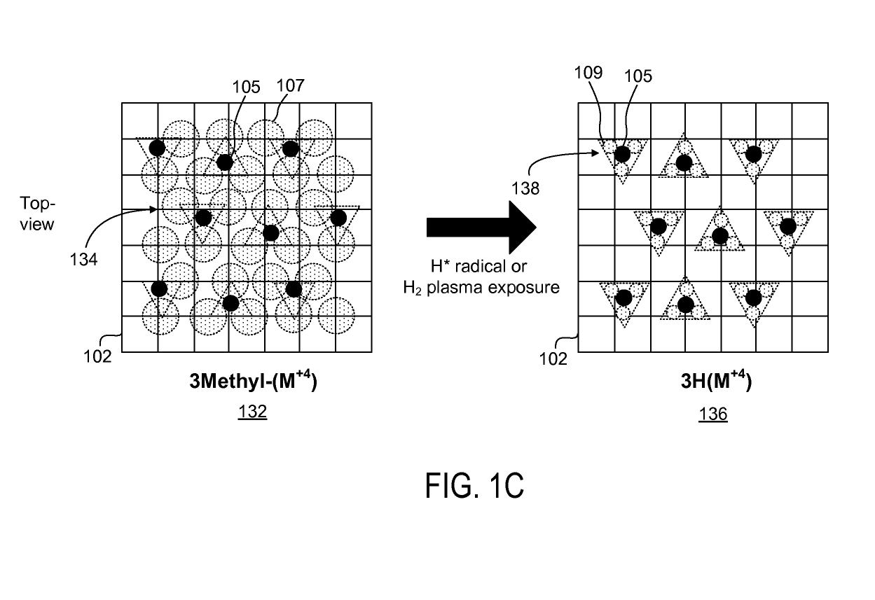

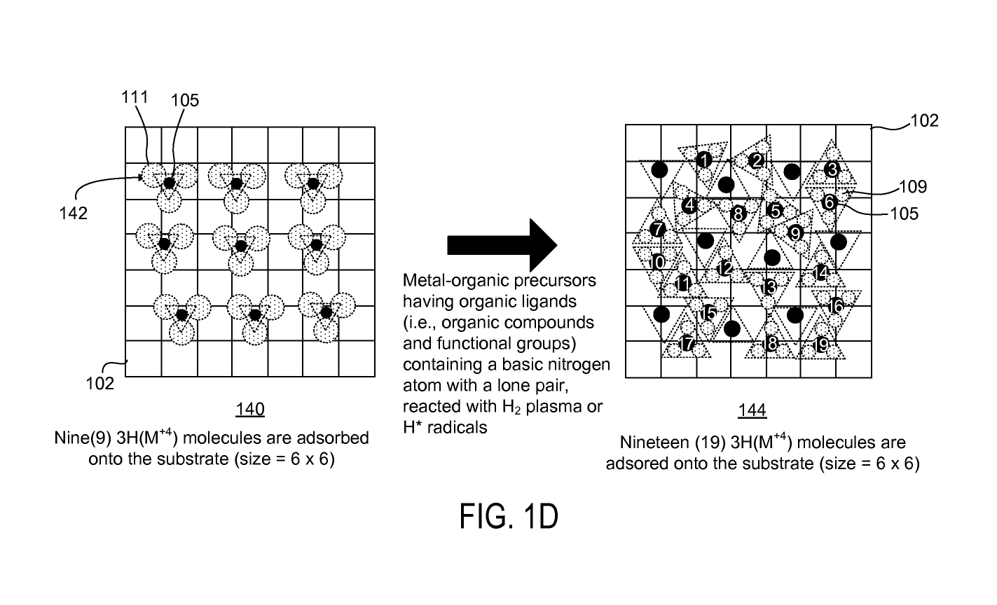

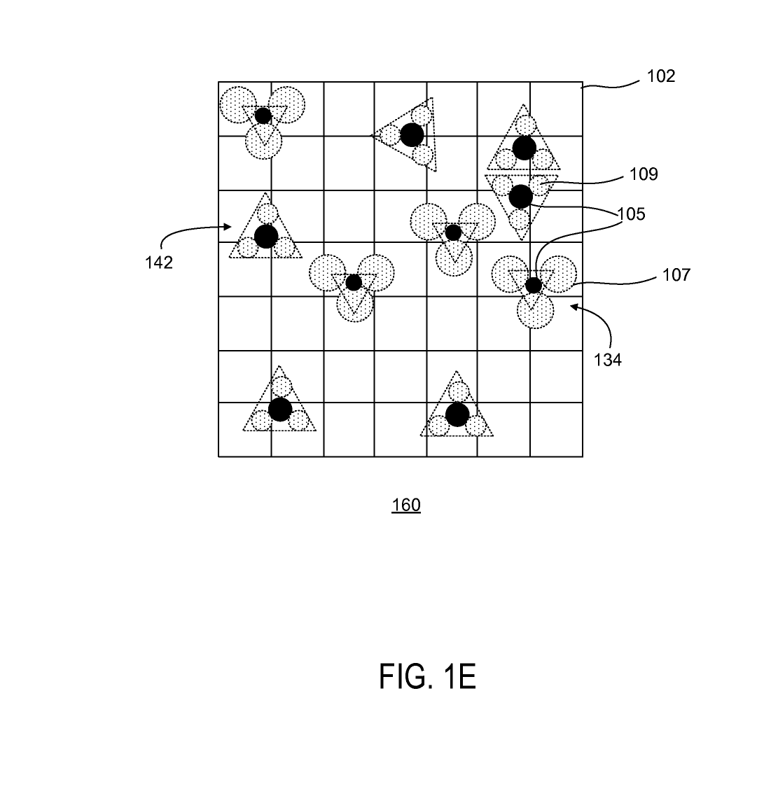

FIG. 1A presents schematic representations (in plan view and side view) of relative molecular sizes of variously valenced metal ions functionalized with methyl groups, in an embodiment. In examples 104, 108, 112, and 116 the metal ions (e.g., metal ion 105) are represented by the smaller circles and the methyl groups (e.g., methyl group 107) are represented by the larger circles; in examples 108 and 116 the largest circles 106 represent the overall molecular size because the locations and angles of atoms are not fixed at their positions. The metal ions, methyl groups, and molecules are shown disposed on a substrate 102 on which a uniformly sized grid is depicted to facilitate comparison of the various molecular sizes.

As shown in example 104, a plan view of a metal ion 105 with a valence of +2 is functionalized with one methyl group 107. While prior to injection the metal ion 105 would have been functionalized with two methyl groups 107, the example 104 depicts the molecule chemisorbed on the surface of the substrate 102, and thus one source precursor methyl ligand is exchanged by a redox reaction with a surface atom or molecule of the substrate. The other precursor ligand, methyl group 107, remains bonded to the metal ion 105. In other examples, more than one ligand (e.g., the methyl group 107 as shown in FIG. 1A) is displaced by reaction with the substrate. The drawings and descriptions herein present the example of a single ligand exchanged for a reaction with a surface atom or molecule of the substrate 102 for convenience of explanation. These depictions are not intended to limit the scope of the present disclosure. As shown in example 108, a plan view of a source precursor molecule chemisorbed to the substrate 102 shows a metal ion 105 with a valence of +3 that is functionalized with two methyl group ligands 107 (alternate views are shown in FIG. 116). As shown in example 112, a plan view of source precursor molecule includes a metal ion 105 with a valence of +4 that, prior to chemisorption to the substrate 102, was functionalized with four methyl group ligands 107. Upon adsorption onto the substrate, the source precursor molecule has three methyl group ligands that remain bonded to the metal ion 105. As a result, metal ions 105 starting with four methyl group ligands produce deposited films of source precursor having lower areal density due to steric hindrance compared to other examples described herein (i.e., source precursor molecules having two or three methyl group ligands as shown in example 116).

Examples of the metal ions that are functionalized include, but are not limited to: Li (+1); Zn, Co, Ni, Cu, Ag, Mg, CA, Sr, and Ba (+2); Al, Fe, Ga, Y, In, La, Bi, La, Er (+3); Si, Ti, Ge, Zr, Sn, Hf (+4); V, Nb, Ta (+5); Mo, W (+6).

As is apparent from FIG. 1A by comparison of the schematic molecular size relative to the grid shown on the substrate 102, the fewer the number of methyl groups functionalizing a metal ion, the smaller the molecule as a whole. Generally, more molecules will fit in a unit area of a substrate as the size of the molecule decreases. So called steric shielding or steric hindrance occurs when either large ligand size or a higher number of ligands prevents additional source precursor molecules from adsorbing to the surface of the substrate. This is apparent upon comparing example 104, which schematically shows 36 molecules functionalized with two methyl groups prior to deposition, to example 112, which schematically shows nine molecules functionalized with four methyl groups prior to deposition. Thus, it would be beneficial to reduce the molecular size of metal organic source precursor molecules to reduce steric hindrance effects and to increase the number of reactive sites (i.e., metal ions) that can be deposited on a substrate for subsequent reaction with a reactant precursor using ALD, thus increasing the deposition rate of a film and improving various properties of the film.

FIG. 1B schematically illustrates relative molecular sizes of a tetramethyl-metal organic compound and a metal tetrahydride compound. As shown in both view 120 and views 124 and 128, molecules consisting of a metal ion 105 and methyl groups 107 are larger than molecules consisting of the same metal ion 105 bonded to hydrogen 109. For example, the number of tetramethyl metal molecules schematically shown in view 124 on a substrate of a given size is nine, whereas the number of metal tetrahydride molecules schematically shown in view 128 on a substrate of the same size is 36. Thus, as indicated above, it would be helpful to use metal ions bonded to hydrogen to improve the deposition rate of a film and the properties of the film.

However, metal hydride molecules are often challenging to use as source precursor molecules in ALD for a variety of reasons. For example, metal hydride molecules often are not adsorbed to the surface of the substrate, making ALD deposition of a film difficult.

In one embodiment, metal organic source precursor molecules are exposed to hydrogen radicals (or alternatively exposed to an H₂ plasma) after injection onto a substrate and before exposure to reactant precursor molecules. This process employs the superior adherence properties of metal organic molecules compared to hydrides in an adsorption step of the ALD process. This is in contrast to using a metal hydride itself as a source precursor. The organic ligands of the as-deposited metal organic source precursor molecules are thereafter converted to hydrides or the organic ligands are exchanged with hydrogen atoms, both of which have the benefit of using smaller molecules as the ultimate, in situ converted source precursor. This facilitates increased metal ion density per unit area of substrate.

An illustration of this appears in FIG. 1C, which includes a plan view 132 of a substrate 102 on which has been injected and chemisorbed tetravalent metal organic molecule(s) having three methyl ligands 134. The metal organic molecules 134 on the substrate 102 are reacted with hydrogen radicals (or alternatively exposed to an H₂ plasma) to produce or convert in situ the tetravalent metal organic molecule 134 to a molecule having up to three hydrogen atoms 109 or hydrides bonded to the tetravalent metal, as shown in plan view 136. This produces a metal hydride molecule 138. The reduced molecular size of the metal hydride molecule 138 increases the amount of substrate 102 surface area available to newly injected and adsorbed source precursor molecules.

An increase in source precursor areal density is not the only benefit of exposing substrate-adsorbed source precursor molecules to hydrogen radicals. In addition, the exposed precursor molecules are more reactive than their corresponding metal organic predecessors and therefore generally react faster with reactant precursor molecules. This result has the added benefit of introducing (or allow the introduction of) fewer impurities (such as hydrocarbons) in the film, thus increasing the deposition rate of a film. Exposure to hydrogen radicals also reduces impurity levels in the adsorbed source precursor film and in the final film.

FIG. 1D is a schematic representation showing increased density of metal organic molecules on a substrate after reaction with hydrogen plasma, in an embodiment. Plan view 140 shows a substrate 102 having “exposed” or “converted” source precursor molecules 142 (i.e., exposed to hydrogen radicals or an H₂ plasma), with a resulting reduced molecular size (compared to as-injected metal organic source precursor) and a corresponding increase in available substrate area. In this particular example, the metal organic source precursor includes amine ligands 111, which are organic compounds and functional groups that contain a basic nitrogen atom (N) with a lone pair of electrons. An amine is any member of a family of nitrogen-containing organic compounds that is derived, either in principal or in practice, from ammonia (NH₃). Such metal organic source precursors are shown as having been reacted with hydrogen radicals or H₂ plasma as molecule 142. Plan view 144 shows the increased molecular density of molecules 142 after the substrate 102 has been exposed again to source precursor molecules, some of which are additionally adsorbed onto the substrate. As is shown, the areal density of molecules increases from 9 molecules on a substrate (plan view 140) to 19 molecules on a substrate with the same size (plan view 144). As mentioned above, not only is the areal density of source precursor and/or exposed source precursor molecules (collectively “reaction sites”) increased on the substrate, but overall cohesive strength between exposed source precursor molecules and the substrate is improved, as is the reactivity of exposed source precursor molecules with reactant precursor molecules.

In addition to the example compositions of metal organic source precursors presented above, other examples include: dimethylethylaminealane, tetradimethylaminotitatium, tetraethylmethylaminotitanium, tetradimethylaminohafnium, tetraethylmethylaminohafnium, tetradimethylaminozirconium, tetraethylmethylaminozirconium, hexamethylcyclotrisilazane, trisdimethylaminosilane, bis(tertiary-butylaminosilane), bisdiethylaminosilane, or R¹R²NSiH₃, where R¹ and R² are alkyl groups. In some examples, R¹ and R² include alkyl groups comprising from two carbon atoms to four carbon atoms. In some embodiments, the alkyl groups comprising from two carbon atoms to four carbon atoms are ethyl, n-propyl, iso-propyl, n-butyl, iso-butyl, sec-butyl, tert-butyl, and cyclic alkyls.

Still other examples metal organic source precursors injected onto a surface of a substrate include: plasmas of O₂, N₂O, O₃, and combinations thereof, that are used to produce oxide films; mixtures of O₂ and NH₃, N₂O and NH₃, and O₃ and NH₃; and N₂, a mixture of N2 and H₂, and a mixture of N₂ and NH₃.

Furthermore, while the examples presented above describe source precursor reaction with various forms of hydrogen, other species may also be used to react with source precursor. For example, metal organic source precursor is reacted with NH₃ radicals either alone or in combination with hydrogen radicals. Specific embodiments of combinations of NH₃ radicals and hydrogen radicals include generating radicals from a mixture of H₂ and NH₃ gases, or generating radicals of each gas separately, and either simultaneously or serially exposing source precursor injected on the surface of the substrate to radical species generated from each of the gases. In other examples, metal organic source precursor is reacted with N₂O radicals, either alone or in combination with radicals of H₂. As with the preceding example, combinations of the gases include generating radicals from a mixture of H₂ and N₂O gases, or generating radicals of each gas separately, and either simultaneously or serially exposing source precursor injected on the surface of the substrate to radical species generated from each of the gases.

Examples of reactant precursors include, but are not limited to, O₂, N₂O, O₃, or any combination thereof,

FIG. 1E is a schematic representation 160 showing a substrate 102 on which are disposed source precursor molecules having both organic ligands 134 (not having reacted with a hydrogen plasma) and converted source precursor molecules 138 in which hydrogen has replaced the organic ligands, in an embodiment. The representation 160 is characteristic of an intermediate state of layer ALD layer deposition, in which as-injected source precursor (with organic ligands) 134 is present on the substrate during exposure to hydrogen radicals even as some of the as-injected source precursor has already reacted (or been “converted”) with hydrogen as described above. The representation 160 is also representative of a final state in which the reaction between as-injected source precursor and hydrogen plasma has already occurred, but has not converted every molecule of the as-injected source precursor. Regardless, molecules of source precursor with organic ligands are disposed on the same substrate as “converted” molecules 138 of source precursor having hydrogen 109 instead of organic ligands.

### Fabrication Method

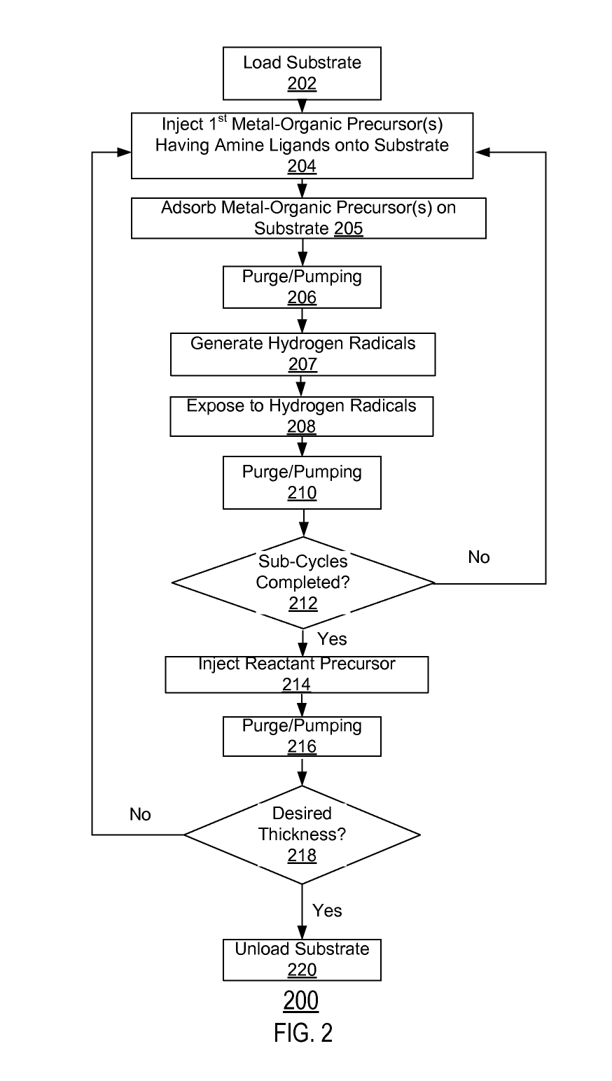

FIG. 2 illustrates an ALD method 200 using source precursors transformed by hydrogen radical exposure for increasing the molecular density and layer deposition rate on a substrate, in an embodiment.

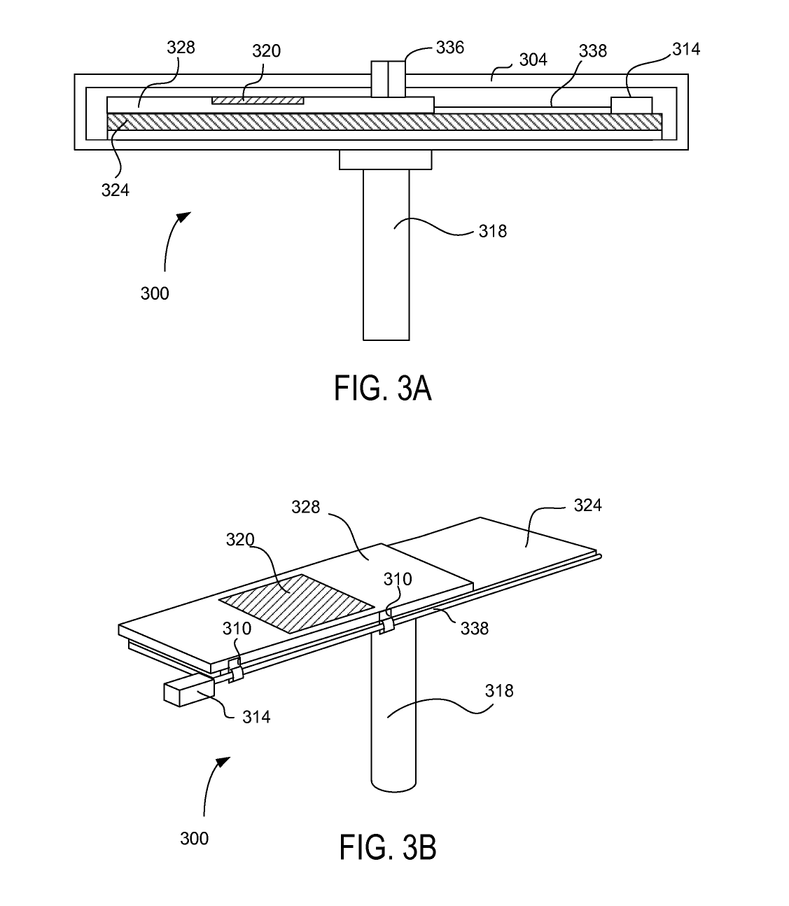

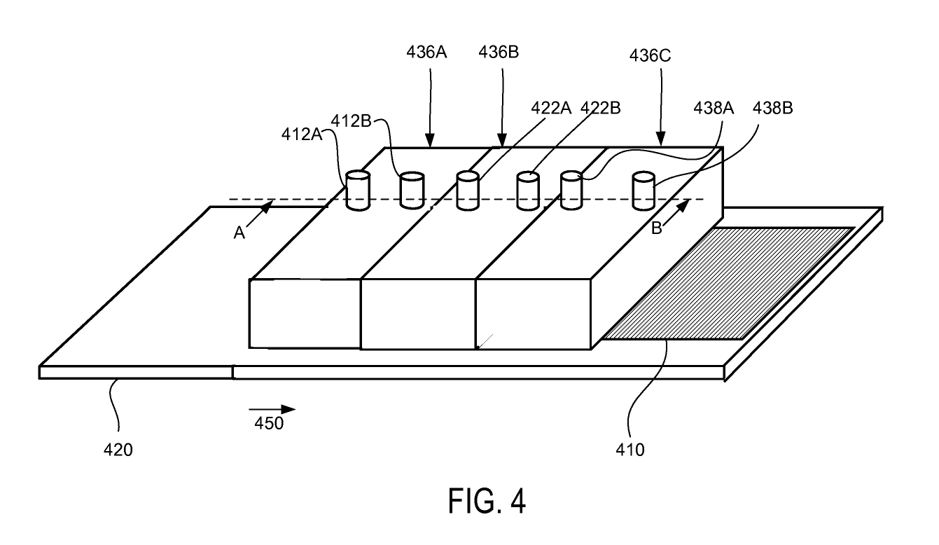

A substrate is loaded 202 into a deposition device. Example deposition devices are described below in the context of FIGS. 3A, 3B, 4, and 5. A first metal organic precursor (or precursors) is injected 204 onto the substrate and adsorbed 205 thereto. In one example, the first metal organic precursor includes amine ligands, although other ligands may also be used, such as dimethyl, trimethyl, tetramethyl, alkyl, and alkoxide ligands. Excess first metal organic precursor (typically the source precursor physisorbed on the substrate) are removed by either purging and/or pumping 206. After purging, the remaining source precursor includes fully saturated chemisorbed molecules, partially saturated chemisorbed molecules, or saturated chemisorbed molecules with physisorbed molecules onto the substrate. The presence of species such as physisorbed molecules in addition to chemisorbed molecules increases the layer deposition rate. Hydrogen radicals are generated 207. The first metal organic precursor molecules remaining on the substrate are exposed 208 to hydrogen radicals. As explained above, this exposure reduces source precursor molecular size, increases areal density of source precursor molecules on a substrate, increases thin film deposition rate, and can improve various physical, chemical, electrical, and optical properties of the thin film deposited by ALD.

If it is determined that the sub-cycle of steps 204 to 210 of the method 200 (i.e., the steps from injecting the source precursor 204 to the purging and/or pumping 210) is not completed 212, the sub-cycle can be repeated one or more times. If the sub-cycle is completed 212, then reactant precursor is injected 214 followed by removal of excess reactant precursor and/or reaction products using purging and/or pumping 216.

If the deposited film is determined 218 not be a desired thickness, then the entire process 200 is optionally repeated one or more times from steps 204 to 218. If it is determined 218 that the film is the desired thickness, the ALD process is completed and the substrate is unloaded 220.

### Example Reactants and Experimental Results

While the embodiments described herein are applicable to any of a variety of chemical systems, several specific chemical systems are described below. In Example 1 shown in Table 1 below, diethyl zinc (“DEZ”) (C₂H₅)₂Zn is used as a source precursor in an application of the embodiments of the present disclosure. In this example, DEZ is used as a source precursor that includes an alkyl ligand. The DEZ source precursor is injected onto a substrate and subsequently exposed to hydrogen radicals (or H₂ plasma), as described above. The exposed source precursor is then reacted with reactant precursor N₂O to produce a thin film of zinc oxide (ZnO). The deposition rate and the refractive index “n” of a zinc oxide film produced using conventional ALD is shown for reference as indicated as “DEZ→N₂O*” in Table 1 below. The deposition rate and the refractive index “n” of a zinc oxide (ZnO) film produced using DEZ exposed to hydrogen radicals according to embodiments of the present disclosure appears as indicated as “DEZ→H*→N₂O*” of Table 1.

TABLE 1

Results

| | Dep. rate | |
|---|---|---|
| Process | (Å/cycle) | n |
| DEZ → N₂O* | 0.62 | 1.864 |
| DEZ → H* → N₂O* | 0.63 | 1.895 |

As seen in Table 1, the deposition rate and refractive index “n” increased, but not conspicuously, in the deposition process using DEZ exposed to hydrogen radicals according to embodiments of the present disclosure. It is believed that this is because the aerial density of the adsorbed precursors is similar to the size of the precursors reacted with hydrogen radicals.

In Example 2 shown in Table 2 below, Titanium Tetrakis IsoPropoxide (“TTIP”) (Ti(O-i-C₃H₇)₄) is used as a source precursor. In this example TTIP is an application of the embodiments of the present disclosure to a source precursor having an alkoxide ligand. One particular challenge when using TTIP in ALD at low deposition temperatures is that TTIP typically deposits layers of material that are in an amorphous state.

The TTIP source precursor is injected onto a substrate and subsequently exposed to hydrogen radicals (or H₂ plasma), as described above. The exposed TTIP source precursor is then reacted with reactant precursor N₂O to produce a thin film of titanium dioxide (TiO₂). The deposition rate and the refractive index “n” of a TiO₂ film produced using conventional ALD without hydrogen radical exposure is shown for reference as indicated as “TTIP→N₂O*” in Table 2. The deposition rate and the refractive index “n” of a TiO₂ film produced using TTIP exposed to hydrogen radicals according to embodiments of the present disclosure appears as indicated as “TTIP→H*→N₂O*” in Table 2.

TABLE 2

Results

| | Dep. rate | |
|---|---|---|
| Process | (Å/cycle) | n |
| TTIP → N₂O* | 0.30 | 2.336 |
| TTIP → H* → N₂O* | 0.38 | 2.374 |

As seen in Table 2, the deposition rate and refractive index “n” increased conspicuously in the deposition process using embodiments of the present disclosure, including exposure of source precursor molecules to hydrogen radicals, because the aerial density of the adsorbed precursors is increased by the reaction with the hydrogen radicals.

In Example 3 shown in Table 3, tetradimethylaminotitanium (“TDMAT”) Ti(N(CH₃)₂)₄ is used as a source precursor in an application of the embodiments of the present disclosure to a source precursor having an amine ligand.

The TDMAT source precursor is injected onto a substrate and subsequently exposed to hydrogen radicals (or H₂ plasma), as described above. The exposed source precursor is then reacted with reactant precursor N₂O to produce a thin film of titanium oxide (TiO₂). The deposition rate and the refractive index “n” of a TiO₂ film produced using conventional ALD is shown for reference as indicated as “TDMAT→N₂O*” in Table 3. The deposition rate and the refractive index “n” of a TiO₂ film produced using embodiments of the present disclosure appears as indicated as “TDMAT→H*→N₂O*” in Table 3.

TABLE 3

Results

| | Dep. rate | |
|---|---|---|
| Process | (Å/cycle) | n |
| TDMAT → N₂O* | 0.58 | 2.340 |
| TDMAT → H* → N₂O* | 0.67 | 2.390 |

As seen in Table 3, the deposition rate and refractive index “n” increased conspicuously in the deposition process using TDMAT exposed to hydrogen radicals according to embodiments of the present disclosure, including exposure of source precursor molecules to hydrogen radicals.

In a variation of the Example 3 presented above in the context of Table 3, Table 4 shows, as indicated as “TDMAT→H*→TDMAT→N₂O*”, results from Example 4 in which a reaction of TDMAT with hydrogen radicals is carried out, then followed by a second injection of TDMAT onto the substrate. After the second injection of TDMAT source precursor, reactant precursor N₂O is injected. This is compared to the results shown as “TDMAT→TDMAT→N₂O*” in Table 4, in which two applications of TDMAT are repeated without an intervening exposure of TDMAT to hydrogen radicals.

TABLE 4

Results

| | Dep. rate | |
|---|---|---|
| Process | (Å/cycle) | n |
| TDMAT → H* → TDMAT → N₂O* | 0.90 | 2.259 |
| TDMAT → TDMAT → N₂O* | 0.62 | 2.263 |

As shown, the deposition rate of the processing using hydrogen radicals is greater than that of the process that does not use hydrogen radicals.

For example, various chemical species having one or more amine ligands are used as a source precursor. The specific amine is selected based on the valence of the metal ion. For example, trivalent metal ions can be bonded with dimethylethylaminealane (2.AlH₂NH(CH₃)(C₂H₅)) (“DMEAA”). Tetravalent metal ions can be bonded with, for example, tetraethylmethylaminotitanium (Ti[N(C₂H₅)(CH₃)]₄), (“TEMAT”), tetraethylmethylaminohafnium (Hf[N(C₂H₅)(CH₃)]₄) (TEMAHf), or tetraethylmethylaminozirconium (Zr[N(C₂H₅)(CH₃)]₄) (TEMAZr). For Si-based precursors, hexamethylcyclotrisilazane ((CH₃)₆(NH)₃Si₃), (“HMCTS”), Trisdimethylaminosilane (SiH[N(CH₃)₂]₃) (TDMAS), bis(tertiary-butylaminosilane) (SiH₂(NHtBu)₂) (“BTBAS”), bisdiethylaminosilane (SiH₂[N(C₂H₅)₂]₂ (BDEAS)) or R¹R²NSiH₃, where R¹ and R² are alkyl groups (e.g., C₂₋₄ alkyl groups, such as ethyl, n-propyl, iso-propyl, n-butyl, iso-butyl, sec-butyl, tert-butyl, and cyclic groups, for example, di-sec-butylaminosilane SiH₃[N(C₄H₉)₂] (DSBAS)) can be used. These are merely examples illustrating some of the amine species that can be used.

### Example Apparatus

FIG. 3A is a cross sectional diagram of a linear deposition device 300, according to one embodiment. FIG. 3B is a perspective view of the linear deposition device 300 (without chamber walls to facilitate explanation), according to one embodiment. The linear deposition device 300 may include, among other components, a support pillar 318, the process chamber 304 and one or more reactors 336. The reactors 336 may include one or more of injectors and radical reactors. Each of the injectors injects source precursors, reactant precursors, purge gases or a combination of these materials onto the substrate 320.

The process chamber 304 enclosed by the walls may be maintained in a vacuum state to prevent contaminants from affecting the deposition process. The process chamber 304 contains a susceptor 328 which receives a substrate 320. The susceptor 328 is placed on a support plate 324 for a sliding movement. The support plate 324 may include a temperature controller (e.g., a heater or a cooler) to control the temperature of the substrate 320. The linear deposition device 300 may also include lift pins (not shown) that facilitate loading of the substrate 320 onto the susceptor 328 or dismounting of the substrate 320 from the susceptor 328.

In one embodiment, the susceptor 328 is secured to brackets 310 (shown in FIG. 3B) that move across an extended bar 338 with screws formed thereon. The brackets 310 have corresponding screws formed in their holes receiving the extended bar 338. The extended bar 338 is secured to a spindle of a motor 314, and hence, the extended bar 338 rotates as the spindle of the motor 314 rotates. The rotation of the extended bar 338 causes the brackets 310 (and therefore the susceptor 128) to make a linear movement on the support plate 324. By controlling the speed and rotation direction of the motor 314, the speed and the direction of the linear movement of the susceptor 328 can be controlled. The use of a motor 314 and the extended bar 338 is merely an example of a mechanism for moving the susceptor 328. Various other ways of moving the susceptor 328 (e.g., use of gears and pinion at the bottom, top or side of the susceptor 328). Moreover, instead of moving the susceptor 328, the susceptor 328 may remain stationary and the reactors 336 may be moved.

While a linear deposition device 300 is shown, other configurations of the deposition device can be used, including a rotating deposition device with a turntable in which the susceptor and the reactors rotate with different angular speeds relative to one another, and a roll-to-roll deposition device with rotating cylindrical drums in which the susceptor and the reactor rotate relative to one another.

FIG. 4 is a perspective view of reactors 436A, 436B, and 436C (collectively referred to as the “reactors 436”) that correspond to reactor 336 in the deposition device 300 of FIG. 3, according to one embodiment. In FIG. 4, the reactors 436A, 436B, and 436C are placed adjacent to one another. In other embodiments, the reactors 436A, 436B, and 436C may be placed with a distance from each other. As the substrate 420 moves from the left to the right (as shown by arrow 450), the substrate 420 is sequentially injected with materials by the reactors 436A, 436B, and 436C to form a deposition layer 410 on the substrate 420. In some examples, instead of the substrate 420 moving from right to left (and back), the reactors 436A, 436B, and 436C may move from the right to the left (and back) while injecting the source precursor materials, hydrogen radicals, or the reactant precursor materials.

In one or more embodiments, the reactor 436A is a gas injector that injects source precursor materials onto the substrate 420. The reactor 436A is connected to a pipe (not shown) to receive the source precursor from a source (e.g., a canister). The source precursor is injected onto the substrate 420, forming one or more layers of source precursor molecules on the substrate 420. Excess source precursor molecules are exhausted via exhaust pipes 412A, 412B.

The reactor 436B may be a hydrogen radical reactor that generates radicals from hydrogen gas. As described above, the hydrogen radicals (produced, for example, by hydrogen plasma) are reacted with the organic groups functionalizing a metal ion so that the size of the source precursor molecule as injected onto the substrate 420 is reduced. In one embodiment, the reactor 436B may also be used to inject a second dose of source precursor molecules after exposure of adsorbed source precursor to hydrogen radicals so that the areal density of reaction sites (i.e., both source precursor molecules and source precursor molecules previously reacted with hydrogen radicals) on the substrate 420 is increased. In another embodiment, the direction of travel of the substrate 420 can be reversed (i.e., 180° from the direction indicated by arrow 450) after exposure to hydrogen radicals so that the substrate is exposed to a second dose of source precursor molecules in reactor 436A. Reaction products from the reaction between the hydrogen radicals and the source precursor molecules, hydrogen radicals themselves, and/or excess source precursor molecules injected in the second dose can be discharged from the reactors 436B via exhaust pipes 422A and 422B.

The reactor 436C may be a radical reactor that generates radicals of gas or a gas mixture, such as N₂O*, received from one or more sources (e.g., canisters). The radicals of gas or gas mixture may function as reactant precursor that forms an atomic layer of materials on the substrate 420 in conjunction with the source precursor. The gas or gas mixtures are injected into the reactor 436C via a pipe (not shown), and are converted into radicals within the reactor 436C by applying voltage across electrodes. The radicals are injected onto the substrate 420, and remaining radicals and/or gas reverted to inactive state are discharged from the reactor 436C via exhaust pipes 438A, 438B.

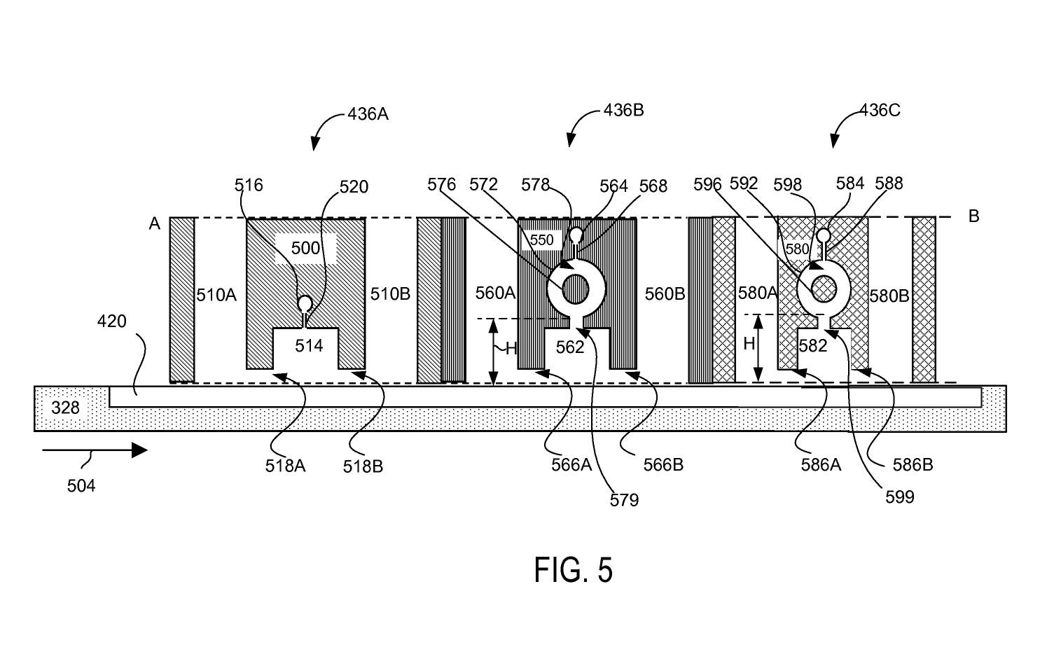

FIG. 5 is a cross sectional diagram illustrating the reactors 436A, 436B, and 436C taken along line A-B of FIG. 4, according to one embodiment. The injector 436A includes a body 500 formed with a gas channel 516, perforations (slits or holes) 520, a reaction chamber 514, constriction zones 518A, 518B, and exhaust portions 510A, 510B. The source precursor is injected into the reaction chamber 514 via the gas channel 516 and the perforations 520. The region of the substrate 420 below the reaction chamber or space filled with precursors 514 comes into contact with the source precursor and adsorbs source precursor molecules on its surface. The excess source precursor (i.e., source precursor remaining after the source precursor is adsorbed on the substrate 420) passes through the constriction zones 518A, 518B, and is discharged via the exhaust portions 510A, 510B. The exhaust portions 510A, 510B are connected to the exhaust pipes 412A, 412B as shown in FIG. 4.

While the source precursor molecules pass through the constriction zones 518A, 518B, physisorbed source precursor molecules are at least partially removed from the region of the substrate 420 below these zones 518A, 518B because higher flow speed of the source precursor below the constriction zone reduces the pressure. This configuration reduces the chances of re-adsorption of by-products on the substrate, such as ligands disengaged from the precursors, which then improves physical and chemical performance (e.g., homogeneity and areal density) of the deposited film.

In one or more embodiments, the injector 436A may also inject purge gas onto the substrate 420 to remove physisorbed source precursor molecules from the substrate 420 and by-products, leaving chemisorbed source precursor molecules on the substrate 420. In this way, an ALD process yielding a high quality atomic layer can be obtained by reducing the presence of by-products compared to conventional ALD processes.

The radical reactor 436B has a similar structure as the injector 436A except that the radical reactor further includes a plasma generator. The plasma generator includes an inner electrode 576 and an outer electrode 572 surrounding a plasma chamber 578 (the outer electrode 572 may be part of a metallic body 550). The body 550 is formed with, among other features, a gas channel 564, perforations (slits or holes) 568, the plasma chamber 578, an injector slit 579, a reaction chamber 562 and exhaust portions 560A, 560B. Hydrogen gas is injected via the channel 564 and perforations 568 into the plasma chamber 578. By applying a voltage difference between the inner electrode 576 and the outer electrode 572, plasma is generated in the plasma chamber 578. As a result of the plasma, hydrogen radicals are generated within the plasma chamber 578. The generated hydrogen radicals are injected into the reaction chamber 562 via the injector slit 579. The region of the substrate 420 below the reaction chamber 562 comes into contact with the hydrogen radicals. As described above, exposing source precursor molecules on the substrate 420 to hydrogen radicals converts the organically functionalized metal organic molecules to smaller, hydrogen functionalized metal molecules.

The distance H between the plasma chamber 578 and the substrate 120 is configured so that a sufficient amount of radicals reach the substrate 120 in an active state. Radicals have a predetermined lifetime. Hence, as the radicals travel via the injector slit 579 and the reaction chamber 562 to the substrate 420, some of the radicals revert back to an inactive gaseous state. With the increase in the travel distance, the amount of radicals reverting to the inactive gaseous state increases. Hence, it is advantageous to set the distance H to be less than a certain length for providing close-proximity (CP) plasma for short lifespan radicals such as H* radicals and N* radicals. For example, the distance H is set to 10 to 100 mm, and preferably shorter than 30 mm, if the plasma gas or radicals exit from the plasma reactor or injector with 1 m/s velocity. Higher velocity will allow longer distance such as 100 mm with 10 m/s velocity.

The reactor 436C has a structure similar to the injector 436B and likewise includes a plasma generator. The plasma generator includes an inner electrode 596 and an outer electrode 592 surrounding a plasma chamber 598 (the outer electrode 592 may be part of a metallic body 580). The body 580 is formed with, among others, a gas channel 584, perforations (slits or holes) 588, the plasma chamber 598, an injector slit 588, a reaction chamber 582 and exhaust portions 580A, 580B. A gas or a mixture of gases, such as N₂O or N₂O +NH₃, is injected via the channel 584 and perforations 588 into the plasma chamber 598. By applying a voltage difference between the inner electrode 596 and the outer electrode 592, plasma is generated in the plasma chamber 598. This configuration is often referred to as coaxial capacitive coupled plasma (coaxial-CCP). As a result of the plasma, radicals of the gas or the mixture of gases are generated within the plasma chamber 598. The generated radicals are injected into the reaction chamber 582 via the injector slit 599. The region of the substrate 420 below the reaction chamber 582 comes into contact with the radicals, forming the deposited layer 410 on the substrate 420. This is referred to as CCP-plasma ALD.

As with reactor 436B, the distance H between the plasma chamber 598 and the substrate 420 is configured so that a sufficient amount of radicals reach the substrate 420 in an active state. Hence, it is advantageous to set the distance H to be less than a certain length. For example, the distance H is set to 10 to 80 mm.

When using radicals of nitrogen containing gas, hydrogen gas, or its mixtures (e.g., NH₃, H₂, N₂/H₂ mixture, N₂/NH₃ mixture), the lifespan of the radicals is relatively short and most of the radicals revert back to an inactive state if the distance H is 80 mm or more. Hence, the distance H is set to be less than 80 mm when using radicals of nitrogen or hydrogen containing gas.

In one embodiment, the radical reactor 436C injects a second dose of source precursor onto the substrate 420 so that the areal density of reaction sites adsorbed on the surface of the substrate 420 increases. In another embodiment, the substrate 420 is returned to the reactor 436A after exposure to the hydrogen plasma (i.e., opposite the direction of travel indicated by arrow 504) so that a second dose of source precursor can be injected onto the substrate.

### Additional Considerations

The foregoing description of the embodiments of the disclosure has been presented for the oxide ALD films and for the purpose of illustration; it is not intended to be exhaustive or to limit the claims to the precise forms disclosed. Persons skilled in the relevant art can appreciate that many modifications for the nitride ALD films via N₂ plasma or N₂+H₂ plasma and variations are possible in light of the above disclosure.

What is claimed is:

1. A method of atomic layer deposition (ALD), the method comprising:
injecting a metal organic source precursor onto a substrate;
adsorbing the metal organic precursor on a surface of the substrate;
generating hydrogen radicals;
exposing the metal organic source precursor on the surface of the substrate to the hydrogen radicals, the hydrogen radicals reacting with the metal organic source precursor on the surface of the substrate; and
injecting a reactant precursor onto the substrate, the reactant precursor reacting with the metal organic source precursor exposed to the hydrogen radicals.

2. The method of claim 1, further comprising injecting additional metal organic source precursor onto the surface of the substrate after exposing the metal organic source precursor on the surface of the substrate to the hydrogen radicals but before injecting the reactant precursor onto the substrate.

3. The method of claim 1, wherein the metal organic source precursor includes an amine ligand.

4. The method of claim 1, wherein the metal organic source precursor includes a metal atom having a valence of three or more.

5. The method of claim 1, wherein the metal organic source precursor includes one of dimethylethylaminealane, tetradimethylaminotitatium, tetraethylmethylaminotitanium, tetradimethylaminohafnium, tetraethylmethylaminohafnium, tetradimethylaminozirconium, tetraethylmethylaminozirconium, hexamethylcyclotrisilazane, trisdimethylaminosilane, bis(tertiary-butylaminosilane), bisdiethylaminosilane, or R¹R²NSiH₃, where R¹ and R² are alkyl groups.

6. The method of claim 5, wherein the alkyl groups of R¹ and R² include alkyl groups having from two carbon atoms to four carbon atoms.

7. The method of claim 6, wherein the alkyl groups include ethyl, n-propyl, iso-propyl, n-butyl, iso-butyl, sec-butyl, tert-butyl, and cyclic alkyls.

8. The method of claim 1, wherein exposing the metal organic source precursor on the surface of the substrate to the hydrogen radicals causes a hydrogen radical to replace an organic ligand of the metal organic source precursor, thereby reducing a molecular size of the metal organic source precursor.

9. The method of claim 1, wherein the metal organic source precursor on the surface of the substrate is also exposed to NH₃ radicals, the metal organic source precursor reacting with the NH₃ radicals and the hydrogen radicals.

10. The method of claim 1, wherein injecting the reactant precursor onto the surface of the substrate reacts the reactant precursor with the metal organic source precursor exposed to the hydrogen radicals.

11. The method of claim 1, wherein the reactant precursor injected onto the surface of the substrate is a plasma of O₂, N₂O, O₃, or a combination thereof, for producing an oxide film.

12. The method of claim 1, wherein the reactant precursor injected onto the surface of the substrate is a plasma produced from a mixture of one of (O₂ and NH₃, N₂O and NH₃, and O₃ and NH₃.

13. The method of claim 1, wherein the reactant precursor injected onto the surface of the substrate is one of a plasma of N₂, a mixture of N₂ and H₂, and a mixture of N₂ and NH₃.

14. An atomic layer deposition film, comprising:
a substrate having a surface;
a plurality of metal organic source precursor molecules comprising a first plurality of multi-valent metal ions, at least some of the multi-valent metal ions bonded to the surface of the substrate and at least one organic ligand; and
a plurality of converted source precursor molecules comprising a second plurality of multi-valent metal ions, at least some of the converted source precursor molecules of the second plurality bonded to the surface of the substrate and at least one hydrogen atom, wherein
both the plurality of metal organic source precursor molecules and the plurality of converted source precursor molecules are disposed on the surface of the substrate.

15. The atomic layer deposition film of claim 14, wherein the at least one organic ligand of the plurality of metal organic source precursor molecules comprises an amine.

16. The atomic layer deposition film of claim 14, wherein the multi-valent metal ions of the first plurality and the second plurality has a valence of three or more.

17. The atomic layer deposition film of claim 14, wherein the plurality of metal organic source precursor molecules includes one of dimethylethylaminealane, tetradimethylaminotitatium, tetraethylmethylaminotitanium, tetradimethylaminohafnium, tetraethylmethylaminohafnium, tetradimethylaminozirconium, tetraethylmethylaminozirconium, hexamethylcyclotrisilazane, trisdimethylaminosilane, bis(tertiary-butylaminosilane), bisdiethylaminosilane, and R¹R²NSiH₃, where R¹ and R² are alkyl groups.

18. The atomic layer deposition film of claim 17, wherein the alkyl groups of R¹ and R² include alkyl groups having from two carbon atoms to four carbon atoms.

19. The atomic layer deposition film of claim 18, wherein the alkyl groups include ethyl, n-propyl, iso-propyl, n-butyl, iso-butyl, sec-butyl, tert-butyl, and cyclic alkyls.

20. The atomic layer deposition film of claim 14, wherein the metal organic source precursor includes an amine.
